(19) United States
(12) Patent Application Publication
(10) Pub. No.: US 2026/0020471 A1
(43) Pub. Date: Jan. 15, 2026

(54) DISPLAY DEVICE

(71) Applicant: LG Display Co., Ltd., Seoul (KR)

(72) Inventors: Sungmoo Kim, Goyang-si (KR); HEUMEIL BAEK, Seoul (KR); HoJin Ryu, Goyang-si (KR)

(73) Assignee: LG Display Co., Ltd., Seoul (KR)

(21) Appl. No.: 19/204,201

(22) Filed: May 9, 2025

(30) Foreign Application Priority Data
Jul. 15, 2024 (KR) 10-2024-0092966

(51) Int. Cl. H10K 59/70; H10K 59/122; H10K 59/35; H10K 59/80

(52) U.S. Cl. CPC H10K 59/70; H10K 59/122; H10K 59/35; H10K 59/8792

(57) ABSTRACT

A display device including a first substrate including a plurality of sub pixels; an organic light emitting element disposed in each of the sub pixels and including an anode, an organic emission layer on the anode, and a cathode on the organic emission layer; and an inorganic light emitting element disposed in each of the sub pixels between the anode and the cathode of the organic light emitting element. Further, a first electrode of the inorganic light emitting element is electrically connected to the anode of the organic light emitting element and a second electrode of the inorganic light emitting element is electrically connected to the cathode of the organic light emitting element.

### CROSS-REFERENCE TO RELATED APPLICATIONS

This application claims priority to Korean Patent Application No. 10-2024-0092966, filed on Jul. 15, 2024, in the Korean Intellectual Property Office, the entire contents of of which is hereby expressly incorporated by reference into the present application.

### BACKGROUND

### Field

The present disclosure relates to a display device, and more particularly, to a display device using a light emitting diode (LED) and an organic light emitting diode (OLED).

### Description of the Related Art

Display devices used for a monitor of a computer, a television, or a cellular phone, for example, include an organic light emitting display device (OLED) which is a self-emitting device and a liquid crystal display device (LCD) which requires a separate light source. The display device is diversified to include personal digital assistants as well as monitors of computers and televisions and a display device with a large display area and a reduced volume and weight is being studied.

Further, in recent years, a display device including an OLED and a display device including an LED are attracting attention as a next generation display device. The OLED has an excellent contrast ratio and a color representation rate to have an excellent image quality and does not have a separate back light so that a display device with a small thickness can be provided. Also, the LED is formed of an inorganic material so that the reliability is excellent and a life span is relatively long. Further, the LED has a fast lighting speed, excellent luminous efficiency, and a strong impact resistance so that a stability is excellent and an image having a high luminance can be displayed.

### SUMMARY

Accordingly, an object to be achieved by the present disclosure is to provide a display device which is capable of using an organic light emitting element and an inorganic light emitting element together.

Another object to be achieved by the present disclosure is to provide a display device in which an organic light emitting element and an inorganic light emitting element are connected in parallel.

Still another object to be achieved by the present disclosure is to provide a display device in which an inorganic light emitting element having excellent blue light efficiency is used together with an organic light emitting element having excellent red light and green light efficiency.

Still another object to be achieved by the present disclosure is to provide a display device which has an improved luminance uniformity by uniformly dispersing light emitted from a light emitting element.

Still another object to be achieved by the present disclosure is to provide a display device which displays an image with a high luminance at a low power by uniformly dispersing light emitted from a light emitting element.

Objects of the present disclosure are not limited to the above-mentioned objects, and other objects, which are not mentioned above, can be clearly understood by those skilled in the art from the following descriptions.

According to an aspect of the present disclosure, a display device includes a first substrate including a plurality of sub pixels, an organic light emitting element which is disposed in each of the sub pixels and includes an anode, an organic emission layer on the anode, and a cathode on the organic emission layer, and an inorganic light emitting element which is disposed in each of the sub pixels and is disposed between the anode and the cathode. A first electrode of the inorganic light emitting element is electrically connected to the anode and a second electrode of the inorganic light emitting element is electrically connected to the cathode. Accordingly, the organic light emitting element and the inorganic light emitting element are disposed in the sub pixel together to easily implement high luminance light.

Other detailed matters of the exemplary embodiments are included in the detailed description and the drawings. According to the present disclosure, an organic light emitting element and an inorganic light emitting element are used together.

Also, an organic light emitting element and an inorganic light emitting element are connected in parallel to be driven. In addition, an inorganic light emitting element having excellent blue light efficiency is used together with an organic light emitting element having excellent red light and green light efficiency to implement white light with high luminance and high purity.

Further, light emitted from the organic light emitting element and the inorganic light emitting element are uniformly dispersed to improve the luminance uniformity. Light emitted from the organic light emitting element and the inorganic light emitting element are uniformly dispersed to display an image with high luminance and drive the display device at a low power.

The effects according to the present disclosure are not limited to the contents exemplified above, and more various effects are included in the present specification.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a schematic diagram of a display device according to an exemplary embodiment of the present disclosure;

FIG. 2A is a partial cross-sectional view of a display device according to an exemplary embodiment of the present disclosure;

FIG. 2B is a perspective view of a tiling display device according to an exemplary embodiment of the present disclosure;

FIG. 3 is an enlarged plan view of an active area of a display device according to an exemplary embodiment of the present disclosure;

FIG. 4 is a cross-sectional view of a sub pixel of a display device according to an exemplary embodiment of the present disclosure;

FIG. 5A is a graph illustrating a light spectrum according to a viewing angle of an organic light emitting element of a display device according to an exemplary embodiment of the present disclosure;

FIG. 5B is a graph illustrating a light spectrum according to a viewing angle of an inorganic light emitting element of a display device according to another exemplary embodiment of the present disclosure; and

FIG. 6 is a cross-sectional view of a sub pixel of a display device according to another exemplary embodiment of the present disclosure.

### DETAILED DESCRIPTION OF THE EMBODIMENT

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies can be omitted to avoid unnecessarily obscuring the subject matter of the present disclosure. The terms such as “including,” “having,” and “consist of” used herein are generally intended to allow other components to be added unless the terms are used with the term “only”. Any references to singular can include plural unless expressly stated otherwise.

Components are interpreted to include an ordinary error range even if not expressly stated. When the position relation between two parts is described using the terms such as “on”, “above”, “below”, and “next”, one or more parts can be positioned between the two parts unless the terms are used with the term “immediately” or “directly”. When an element or layer is disposed “on” another element or layer, another layer or another element can be interposed directly on the other element or therebetween.

Although the terms “first”, “second”, and the like are used for describing various components, these components are not confined by these terms. These terms are merely used for distinguishing one component from the other components. Therefore, a first component to be mentioned below can be a second component in a technical concept of the present disclosure. Like reference numerals generally denote like elements throughout the specification.

A size and a thickness of each component illustrated in the drawing are illustrated for convenience of description, and the present disclosure is not limited to the size and the thickness of the component illustrated. The features of various embodiments of the present disclosure can be partially or entirely adhered to or combined with each other and can be interlocked and operated in technically various ways, and the embodiments can be carried out independently of or in association with each other.

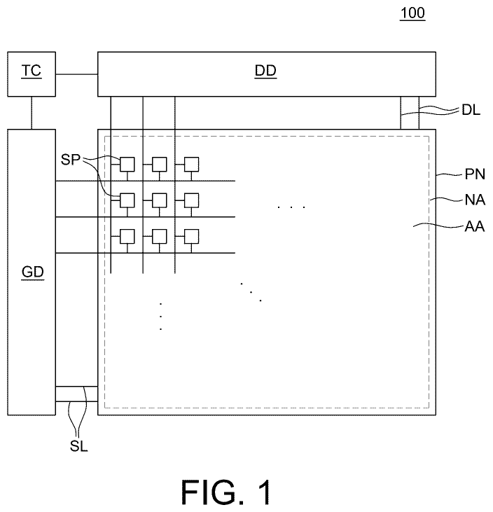

Hereinafter, an exemplary embodiment of the present disclosure will be described in detail with reference to accompanying drawings. FIG. 1 is a schematic diagram of a display device according to an exemplary embodiment of the present disclosure. In FIG. 1, for the convenience of description, among various components of the display device 100, only a display panel PN, a gate driver GD, a data driver DD, and a timing controller TC are illustrated.

Referring to FIG. 1, the display device 100 includes a display panel PN including a plurality of sub pixels SP, a gate driver GD and a data driver DD supplying various signals to the display panel PN, and a timing controller TC controlling the gate driver GD and the data driver DD. In addition, the gate driver GD supplies a plurality of scan signals to a plurality of scan lines SL according to a plurality of gate control signals supplied from the timing controller TC. Even though FIG. 1 illustrates that one gate driver GD is disposed to be spaced apart from one side of the display panel PN, the number of the gate drivers GD and the placement thereof are not limited thereto.

Further, the data driver DD supplies a data voltage to a plurality of data lines DL according to a plurality of data control signals and image data supplied from the timing controller TC. The data driver DD also converts the image data into a data voltage using a reference gamma voltage and can supply the converted data voltage to the data lines DL.

In addition, the timing controller TC aligns image data input from the outside to supply the image data to the data driver DD. The timing controller TC can also generate a gate control signal and a data control signal using synchronization signals input from the outside, such as a dot clock signal, a data enable signal, and horizontal/vertical synchronization signals. Further, the timing controller TC supplies the generated gate control signal and data control signal to the gate driver GD and the data driver DD, respectively, to control the gate driver GD and the data driver DD.

Also, the display panel PN displays images to the user and includes the sub pixels SP. In the display panel PN, of the scan lines SL and the data lines DL intersect each other and the sub pixels SP is connected to intersections of the scan lines SL and the data lines DL.

Further, an active area AA and a non-active area NA can be defined. In particular, the active area AA displays images in the display device 100. In the active area AA, a plurality of sub pixels SP configuring a plurality of pixels PX and a pixel circuit for driving the sub pixels SP can be disposed. The sub pixels SP is a minimum unit which configures the active area AA and n sub pixels SP form one pixel PX. In each of the sub pixels SP, a thin film transistor for driving the light emitting elements can be disposed. The light emitting elements include an organic light emitting diode (OLED), a light emitting diode (LED), or a micro light emitting diode (micro LED).

In the active area AA, a plurality of signal lines which transmits various signals to the sub pixels SP is disposed. For example, the signal lines include a plurality of data lines DL supplying a data voltage to each of the sub pixels SP and a plurality of scan lines SL supplying a scan signal to each of the sub pixels SP. As shown in FIG. 1, the scan lines SL extend to one direction in the active area AA to be connected to the sub pixels SP and the data lines DL extends to a direction different from the one direction in the active area AA to be connected to the sub pixels SP. In addition, in the active area AA, a low potential power line and a high potential power line can be further disposed, but are not limited thereto.

In addition, the non-active area NA does not display images and can be defined as an area extending from the active area AA. In the non-active area NA, a link line transmitting a signal to the sub pixel SP of the active area AA and a pad electrode, or a driving IC, such as a gate driver IC or a data driver IC, can be disposed.

Further, the non-active area NA can be located on a rear surface of the display panel PN, that is, a surface on which the sub pixels SP are not disposed or can be omitted, and is not limited as illustrated in the drawing. In addition, a driver, such as a gate driver GD, a data driver DD, and a timing controller TC, can be connected to the display panel PN in various ways. For example, the gate driver GD can be mounted in the non-active area NA in a gate in panel (GIP) manner or mounted between the sub pixels SP in the active area AA in a gate in active area (GIA) manner.

Also, the data driver DD and the timing controller TC can be formed in separate flexible film and printed circuit board. In addition, the display panel PN can be electrically connected to the data driver DD and the timing controller TC by bonding the flexible film and the printed circuit board to the pad electrode formed in the non-active area NA of the display panel PN.

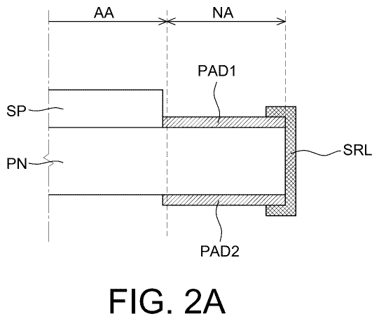

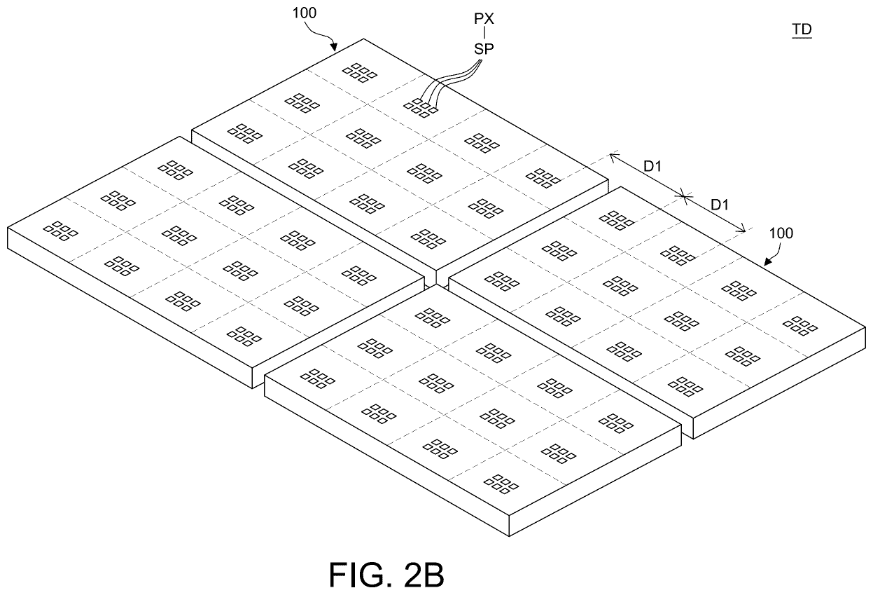

As another example, when the gate driver GD is mounted in the active area AA in the GIA manner and a side line SRL connecting the signal line on the front surface of the display panel PN to the pad electrode on a rear surface of the display panel PN is formed to bond the flexible film and the printed circuit board onto a rear surface of the display panel PN, the non-active area NA on the front surface of the display panel PN can be minimized. Therefore, when the gate driver GD, the data driver DD, and the timing controller TC are connected to the display panel PN as described above, a zero bezel (no bezel) can be substantially implemented, which will be described in more detail with reference to FIGS. 2A and 2B.

In more detail, FIG. 2A is a partial cross-sectional view of a display device, and FIG. 2B is a perspective view of a tiling display device according to an exemplary embodiment of the present disclosure.

In the non-active area NA of the display panel PN, a plurality of pad electrodes for transmitting various signals to the sub pixels SP is disposed. For example, in a non-active area NA on the front surface of the display panel PN, a first pad electrode PAD1 transmitting a signal to the sub pixels SP is disposed. In a non-active area NA on the rear surface of the display panel PN, a second pad electrode PAD2 electrically connected to a driving component, such as a flexible film and the printed circuit board, is disposed.

Also, various signal lines connected to the sub pixels SP, for example, a scan line SL or a data line DL extend from the active area AA to the non-active area NA to be electrically connected to the first pad electrode PAD1. Further, the side line SRL is disposed along a side surface of the display panel PN. In particular, the side line SRL can electrically connect the first pad electrode PAD1 on the front surface of the display panel PN and the second pad electrode PAD2 on the rear surface of the display panel PN. Therefore, a signal from a driving component on the rear surface of the display panel PN can be transmitted to the sub pixels SP through the second pad electrode PAD2, the side line SRL, and the first pad electrode PAD1. Accordingly, a signal transmitting path is formed from the front surface of the display panel PN to the side surface and the rear surface to minimize an area of the non-active area NA on the front surface of the display panel PN.

Further, referring to FIG. 2B, a tiling display device TD having a large screen size can be implemented by connecting a plurality of display devices 100. In addition As illustrated in FIG. 2A, when the tiling display device TD is implemented using a display device 100 with a minimized bezel, a seam area in which an image between the display devices 100 is not displayed is minimized so that a display quality can be improved.

For example, the sub pixels SP form one pixel PX and a distance D1 between an outermost pixel PX of one display device 100 and an outermost pixel PX of another display device 100 adjacent to one display device can be equal to a distance D1 between pixels PX in one display device 100. Accordingly, the interval of the pixels PX between the display devices 100 is constantly configured to minimize the seam area.

However, FIGS. 2A and 2B are illustrative so that the display device 100 according to the exemplary embodiment of the present disclosure can be a general display device with a bezel, but is not limited thereto. Hereinafter, a display panel PN of a display device 100 according to an exemplary embodiment of the present disclosure will be described in more detail.

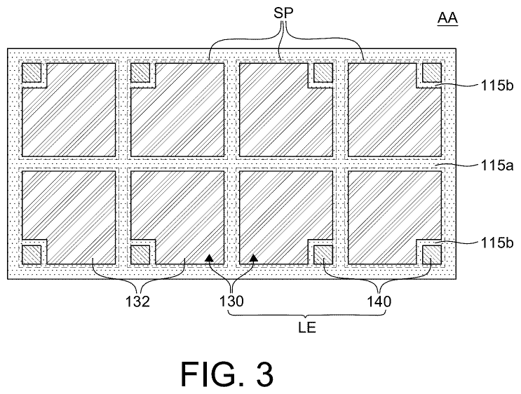

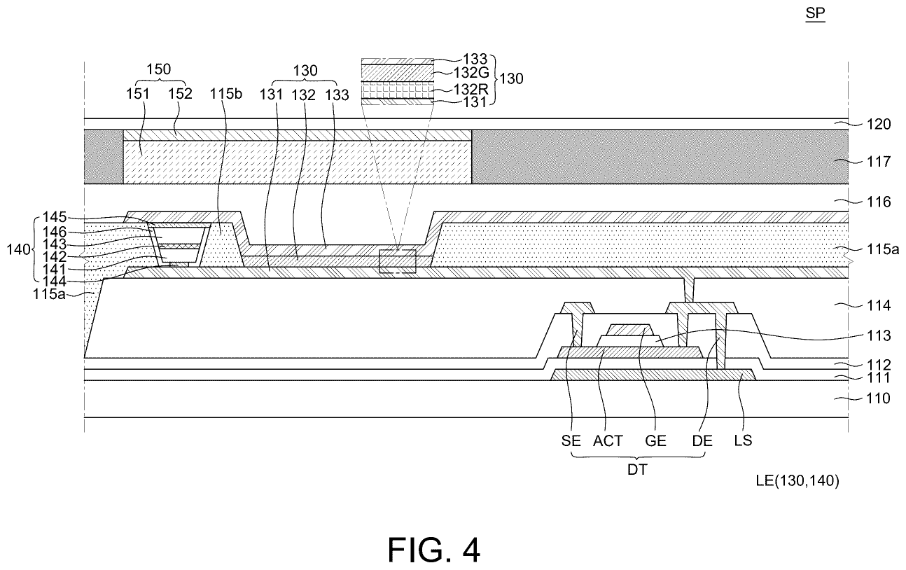

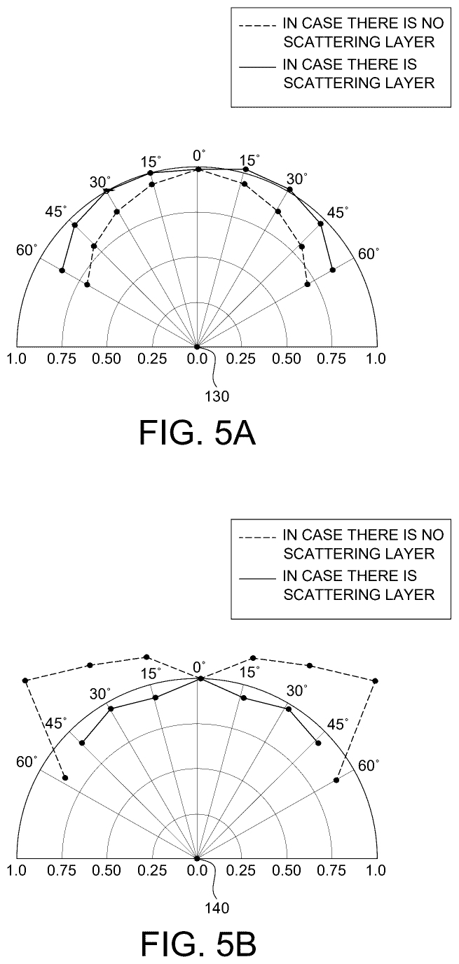

FIG. 3 is an enlarged plan view of an active area of a display device, and FIG. 4 is a cross-sectional view of a sub pixel of a display device according to an exemplary embodiment of the present disclosure. Further, FIG. 5A is a graph illustrating a light spectrum according to a viewing angle and FIG. 5B is a graph illustrating a light spectrum according to a viewing angle of an inorganic light emitting element of a display device according to another exemplary embodiment of the present disclosure. In FIG. 3, for the convenience of description, only an organic emission layer 132, an inorganic light emitting element 140, a first bank 115a, and a second bank 115b of an organic light emitting element 130 of the display panel PN are illustrated.

Referring to FIG. 3, the sub pixels SP are disposed in the active area AA of the display panel PN. As shown, the sub pixels SP can be disposed to be spaced apart from each other with the first bank 115a therebetween. That is, the first bank 115a is disposed in a boundary between the sub pixels SP to define an area of the sub pixels SP.

Also, each of the sub pixels SP includes a plurality of light emitting elements LE. The light emitting elements LE can include an inorganic light emitting element 140 and an organic light emitting element 130. That is, one inorganic light emitting element 140 and one organic light emitting element 130 can be disposed together in one sub pixel SP. White light is implemented by a combination of light emitted from the inorganic light emitting element 140 and light emitted from the organic light emitting element 130. A light conversion member 150 (FIG. 4) is used to convert the white light into various color light. Accordingly, the sub pixels SP of the display device 100 according to the exemplary embodiment of the present disclosure can display various color light by a combination of white light of the inorganic light emitting element 140 and the organic light emitting element 130 and the light conversion member 150.

In each of the sub pixels SP, the inorganic light emitting element 140 and the organic light emitting element 130 can be disposed to be spaced apart from each other. In more detail, the inorganic light emitting element 140 and the organic light emitting element 130 can be disposed to be spaced apart from each other with the second bank 115b therebetween. Therefore, in each of the sub pixels SP, the inorganic light emitting element 140 is disposed in an area between the first bank 115a and the second bank 115b, and the organic light emitting element 130 can be disposed in an area between the first bank 115a and the second bank 115b. In addition, FIG. 4 illustrates a single first bank 115a and a single second bank 115b in each sub pixel. However, multiple banks may be used instead of a single bank. For example, the second bank 115b can be two adjacent second banks thereby extending the length of organic light emitting element 130.

In addition, in each of the sub pixels SP, the inorganic light emitting element 140 is disposed to be biased to one side of the sub pixel SP and the organic light emitting element 130 is disposed in a remaining area. For example, when the sub pixel SP is configured as a rectangular area, the inorganic light emitting element 140 is disposed to be adjacent to one corner of four corners of the sub pixel SP and the organic light emitting element 130 can be disposed in a remaining area of the sub pixel SP. For example, in some sub pixel SP, the inorganic light emitting element 140 is disposed to be adjacent to a left upper corner of the sub pixel SP and in the other sub pixel SP, the inorganic light emitting element 140 can be disposed to be adjacent to a right upper corner of the sub pixel SP.

Also, in another sub pixel SP, the inorganic light emitting element 140 is disposed to be adjacent to a left lower corner of the sub pixel SP and in the other sub pixel SP, the inorganic light emitting element 140 can be disposed to be adjacent to a right lower corner of the sub pixel SP. As another example, the inorganic light emitting element 140 can be disposed to be adjacent to an edge of the opening of the first bank 115a. Two side surfaces, among four side surfaces of the inorganic light emitting element 140, can be disposed to be in contact with the first bank 115a. Accordingly, the inorganic light emitting element 140 is disposed to be adjacent to an edge of the sub pixel SP to ensure an area where an organic emission layer 132 of the organic light emitting element 130 is disposed to the maximum.

Also, FIG. 3 illustrate the sub pixels arranged in a matrix with row and columns in which the inorganic light emitting elements 140 can be arranged in upper and lower corner regions. Two outer edges of the light emitting elements correspond to an outside edge of the corresponding sub pixel. Also, two inner edges of the inorganic light emitting elements 140 are spaced from two inner edges of the organic light emitting elements 130. FIG. 3 illustrate square shaped subpixels arranged into a rectangular shaped active area AA of the display panel. However, the subpixels can be a different shape other than rectangular. In this instance, the inorganic light emitting elements can be arranged on outside edges of the different shaped sub pixel SP.

If the inorganic light emitting element 140 is disposed in a center area of the sub pixel SP, the second bank 115b is disposed so as to enclose four surfaces of the inorganic light emitting element 140 so that an area where the organic light emitting element 130 is disposed in the sub pixel SP can be reduced due to the second bank 115b.

Accordingly, as in the display device 100 according to the exemplary embodiment of the present disclosure, when the inorganic light emitting element 140 is disposed to be biased to one area of the sub pixel SP, the second bank 115b is disposed only between two side surfaces, among four side surfaces of the inorganic light emitting element 140 and the organic emission layer 132. Therefore, the second bank 115b can be disposed in the sub pixel SP to a minimum and a more area can be ensured to dispose the organic emission layer 132.

Referring to FIGS. 3 and 4, the display device 100 includes a first substrate 110, a buffer layer 111, an interlayer insulating layer 112, a gate insulating layer 113, a planarization layer 114, a first bank 115a, a second bank 115b, a protection layer 116, a black matrix 117, a second substrate 120, a light shielding layer LS, a driving transistor DT, an inorganic light emitting element 140, an organic light emitting element 130, and a light conversion member 150.

First, the first substrate 110 supports various components included in the display device 100 and can be formed of an insulating material. For example, the first substrate 110 can be formed of glass or resin. Further, the first substrate 110 can be formed of polymer or plastics or can be formed of a material having flexibility.

Also, the light shielding layer LS is disposed on the first substrate 110 in each of the sub pixels SP. In more detail, the light shielding layer LS can block light incident onto the driving transistor DT, below the first substrate 110. That is, light which is incident onto an active layer ACT of the driving transistor DT is blocked by the light shielding layer LS to minimize a characteristic variation of the driving transistor DT and a leakage current thereby.

Further, the buffer layer 111 is disposed on the first substrate 110 and the light shielding layer LS. In particular, the buffer layer 111 can reduce permeation of moisture or impurities through the first substrate 110. The buffer layer 111 can also be configured by a single layer or a double layer of silicon oxide (SiOx) or silicon nitride (SiNx), but is not limited thereto. However, the buffer layer 111 can be omitted depending on a type of the first substrate 110 or a type of transistor, but is not limited thereto.

In addition, the driving transistor DT is disposed on the buffer layer 111 in each of the sub pixels SP. The driving transistor DT includes an active layer ACT, a gate electrode GE, a source electrode SE, and a drain electrode DE. As shown in FIG. 4, the active layer ACT is disposed on the buffer layer 111 and can be formed of a semiconductor material, such as an oxide semiconductor, amorphous silicon, or polysilicon, but is not limited thereto.

Also, the gate insulating layer 113 is disposed on the active layer ACT. In particular, the gate insulating layer 113 insulates the active layer ACT from the gate electrode GE and can be configured by a single layer or a double layer of silicon oxide (SiOx) or silicon nitride (SiNx), but is not limited thereto. FIG. 4 illustrates the gate insulating layer 113 is partially disposed only in an area above the active layer ACT, but the gate insulating layer 113 can be disposed on the entire first substrate 110, and is not limited thereto.

In addition, the gate electrode GE is disposed on the gate insulating layer 113. The gate electrode GE can be configured by a conductive material, such as copper (Cu), aluminum (Al), molybdenum (Mo), nickel (Ni), titanium (Ti), chrome (Cr), or an alloy thereof, but is not limited thereto. Further, the interlayer insulating layer 112 is disposed on the gate electrode GE. As shown in FIG. 4, in the interlayer insulating layer 112, a contact hole through which the source electrode SE and the drain electrode DE are connected to the active layer ACT is formed. Also, the interlayer insulating layer 112 protects components below the interlayer insulating layer 112 and can be configured by a single layer or a double layer of silicon oxide (SiOx) or silicon nitride (SiNx), but is not limited thereto.

As shown, the source electrode SE and the drain electrode DE are disposed on the interlayer insulating layer 112. In more detail, the source electrode SE and the drain electrode DE can be electrically connected to the active layer ACT through a contact hole of the interlayer insulating layer 112. Further, any one of the source electrode SE and the drain electrode DE is electrically connected to the light shielding layer LS so as not to allow the light shielding layer LS to operate as a floating gate. For example, a voltage is applied to the light shielding layer LS from any one of the source electrode SE and the drain electrode DE so that fluctuation of the voltage of the light shielding layer LS is suppressed and the fluctuation of a threshold voltage of the driving transistor DT caused by the floated light shielding layer LS can be minimized. The source electrode SE and the drain electrode DE can also be configured by a conductive material, such as copper (Cu), aluminum (Al), molybdenum (Mo), nickel (Ni), titanium (Ti), chrome (Cr), or an alloy thereof, but are not limited thereto.

In addition, the planarization layer 114 is disposed on the driving transistor DT and the interlayer insulating layer 112. In particular, the planarization layer 114 can planarize an upper portion of the first substrate 110 on which the driving transistor DT is disposed. The planarization layer 114 can also be configured by a single layer or a double layer, and for example, can be formed of photoresist or an acrylic-based organic material, but is not limited thereto.

Further, the organic light emitting element 130 is disposed on the planarization layer 114 in each of the sub pixels SP. As shown, the organic light emitting element 130 includes an anode 131, an organic emission layer 132, and a cathode 133.

Also, the anode 131 is disposed on the planarization layer 114 and can be electrically connected to any one of the source electrode SE or the drain electrode DE of the driving transistor DT. Further, the anode 131 can be formed of a conductive material having a high work function to supply holes to the organic emission layer 132. For example, the anode 131 can be formed with a transparent conductive material such as indium tin oxide (ITO) and indium zinc oxide (IZO), but is not limited thereto.

In addition, the display device 100 according to the exemplary embodiment of the present disclosure can be configured as a top-emission type. For the top emission type, light emitted from the light emitting element LE can travel toward the top of the light emitting element LE. According to the top emission type, in order to reflect light emitted from the organic emission layer 132 toward the top of the organic light emitting element 130, the anode 131 can further include a reflection layer formed of a metal material having an excellent reflection efficiency, for example, a material, such as aluminum (Al) or silver (Ag). Accordingly, the anode 131 is configured by a layer formed of a transparent conductive material and a reflection layer formed of an opaque conductive material having an excellent reflection efficiency so that light emitted from the organic emission layer 132 is reflected from the anode 131 to travel toward the cathode 133 and the second substrate 120. Further, light emitted from the inorganic light emitting element 140 can travel toward the cathode 133 and the second substrate 120 by the anode 131 having a reflection layer.

Also, the first bank 115a is disposed on the anode 131, divides an area of the sub pixel SP and can be disposed at a boundary between the sub pixels SP. In particular, the first bank 115a is disposed in an area between the sub pixels SP to reduce the color mixture of light of each of the sub pixels SP. The first bank 115a can also include an opening where the organic light emitting element 130 and the inorganic light emitting element 140 are disposed. That is, an opening of the first bank 115a can be disposed so as to overlap an area where the light conversion member 150 is disposed. Accordingly, the opening of the first bank 115a, which is an area where the organic light emitting element 130 and the inorganic light emitting element 140 are disposed and light converted in the light conversion member 150 is emitted can be defined as an emission area where light is substantially emitted.

In addition, the second bank 115b is disposed on the anode 131. The second bank 115b separates the organic emission layer 132 of the organic light emitting element 130 and the inorganic light emitting element 140 and can be disposed between organic light emitting element 130 and the inorganic light emitting element 140 in each of the sub pixels SP. The second bank 115b can also be connected to the first bank 115a and can be integrally formed with the first bank 115a. The second bank 115b can also be disposed so as to enclose the organic emission layer 132 together with the first bank 115a. Further, the second bank 115b can be disposed so as to enclose the inorganic light emitting element 140 together with the first bank 115a. As shown in FIG. 4, the second bank 115b is disposed between the organic emission layer 132 and the inorganic light emitting element 140 so that the organic emission layer 132 and the inorganic light emitting element 140 can not be in direct contact with each other.

Further, the first bank 115a and the second bank 115b are formed of the same material and are formed of an organic insulating material. For example, the first bank 115a and the second bank 115b are formed of polyimide, acrylic or benzocyclobutene (BCB) based resin. However, the first bank 115a and the second bank 115b can be formed of different materials, but are not limited thereto.

In addition, the organic emission layer 132 is disposed on the anode 131 in an area between the first bank 115a and the second bank 115b. The organic emission layer 132 has a structure in which a plurality of organic emission layers 132 which emit different color light are laminated. For example, the organic emission layer 132 can have a structure in which an emission unit including a red organic emission layer 132R which emits red light and an emission unit including a green organic emission layer 132G which emits green light are laminated. Also, the organic light emitting element 130 including the emission unit including a red organic emission layer 132R and the emission unit including a green organic emission layer 132G can emit red light and green light.

FIG. 4 illustrates the red organic emission layer 132R is disposed on the anode 131 and the green organic emission layer 132G is disposed on the red organic emission layer 132R. However, a laminating order of the red organic emission layer 132R and the green organic emission layer 132G can be opposite, but is not limited thereto.

Further, the emission units can further include an organic material layer such as a hole injection layer, a hole transport layer, an electron transport layer, and an electron injection layer. For example, each of the emission unit of the red organic emission layer 132R and the emission unit of the green organic emission layer 132G can include a hole injection layer and a hole transport layer for supplying holes and an electron injection layer and an electron transport layer for supplying electrons. Further, an organic material layer, such as a charge generation layer, can be further disposed between two emission units.

As shown, the cathode 133 is disposed on the organic emission layer 132, the first bank 115a, and the second bank 115b. Also, the cathode 133 is connected to the power line to supply a power voltage to the organic emission layer 132. In addition, the cathode 133 is also formed on the inorganic light emitting element 140 to supply the power voltage to the inorganic light emitting element 140.

In addition, the cathode 133 can be formed of a conductive material having a low work function so as to supply electrons to the organic emission layer 132. For example, the cathode 133 can be formed of a transparent conductive material, such as indium tin oxide (ITO) and indium zinc oxide (IZO) or ytterbium (Yb) alloy and can further include a metal doping layer, but is not limited thereto. The cathode 133 is also electrically connected to a power line to be supplied with a low potential power voltage.

Next, the inorganic light emitting element 140 is disposed between the anode 131 and the cathode 133 in each of the sub pixels SP. In addition, the inorganic light emitting element 140 can be a light emitting diode (LED) or a micro LED. As shown in FIG. 4, the inorganic light emitting element 140 includes a first semiconductor layer 141, an active layer 142, a second semiconductor layer 143, a first electrode 144, a second electrode 145, and a protection film 146. First, the first semiconductor layer 141 is disposed on the anode 131 and the second semiconductor layer 143 is disposed on the first semiconductor layer 141. The first semiconductor layer 141 and the second semiconductor layer 143 can be semiconductor layers doped with p-type and n-type impurities. For example, the first semiconductor layer 141 and the second semiconductor layer 143 can be layers formed by doping p-type and n-type impurities into a material, such as gallium nitride (GaN), indium aluminum phosphide (InAlP), or gallium arsenide (GaAs). The p-type impurity can be magnesium (Mg), zinc (Zn), and beryllium (Be), and the n-type impurity can be silicon (Si), germanium (Ge), and tin (Sn), but are not limited thereto.

In addition, the active layer 142 is disposed between the first semiconductor layer 141 and the second semiconductor layer 143. The active layer 142 can emit light based on a driving current supplied to the inorganic light emitting element 140. For example, the active layer 142 emits blue light and the inorganic light emitting element 140 can be a blue inorganic light emitting element 140. The active layer 142 can also be formed by a single layer or a multi-quantum well (MQW) structure, and for example, can be formed of indium gallium nitride (InGaN) or gallium nitride (GaN), but is not limited thereto.

Further, the first electrode 144 is disposed between the first semiconductor layer 141 and the anode 131 and can be in contact with the bottom surface of the first semiconductor layer 141. The first electrode 144 is an electrode electrically connecting the first semiconductor layer 141 to the anode 131 and the driving transistor DT. Also, the anode 131 extends over the second bank 115b to be in contact with the first electrode 144. The inorganic light emitting element 140 can be electrically connected to the driving transistor DT through the first electrode 144 and the anode 131. In addition, the first electrode 144 can be configured by an opaque conductive material, such as titanium (Ti), gold (Au), silver (Ag), copper (Cu) or an alloy thereof, a transparent conductive material, such as indium tin oxide (ITO) or indium zinc oxide (IZO), or a combination of the opaque conductive material and the transparent conductive material. However, it is not limited thereto.

Also, the second electrode 145 is disposed on the second semiconductor layer 143 and between the second semiconductor layer 143 and the cathode 133. The second electrode 145 electrically connects the inorganic light emitting element 140 and the cathode 133. As shown, the cathode 133 extends over the second bank 115b to be in contact with the second electrode 145. In addition, the inorganic light emitting element 140 can be supplied with a power voltage through the second electrode 145 and the cathode 133. Further, the second electrode 145 is formed of a transparent conductive material, such as indium tin oxide (ITO) or indium zinc oxide (IZO), but is not limited thereto.

As shown in FIG. 4, a protection film 146 encloses the first semiconductor layer 141, the active layer 142, and the second semiconductor layer 143. In particular, the protection film 146 can protect a first semiconductor layer 141, an active layer 142, and a second semiconductor layer 143. The protection film 146 can also be disposed so as to enclose a side surface and a part of a bottom surface of the first semiconductor layer 141, a side surface of the active layer 142, and a side surface of the second semiconductor layer 143. Further, the first electrode 144 and the second electrode 145 are exposed from the protection film 146 to be connected to the anode 131 and the cathode 133. For example, the protection film 146 is formed of an insulating material, such as silicon oxide (SiOx) or silicon nitride (SiNx), but is not limited thereto.

In addition, the anode 131 of the organic light emitting element 130 and the first electrode 144 of the inorganic light emitting element 140 are electrically connected to each other and the cathode 133 of the organic light emitting element 130 and the second electrode 145 of the inorganic light emitting element 140 can be electrically connected to each other. The organic light emitting element 130 and the inorganic light emitting element 140 are also connected in parallel to be driven. Further, the organic light emitting element 130 and the inorganic light emitting element 140 connected in parallel can be driven by only one driving transistor DT. That is, the organic light emitting element 130 and the inorganic light emitting element 140 can be driven by one pixel circuit. Accordingly, the organic light emitting element 130 and the inorganic light emitting element 140 are driven together by only one pixel circuit including one driving transistor DT to simplify a configuration of the pixel circuit.

Also, the protection layer 116 is disposed on the organic light emitting element 130 and the inorganic light emitting element 140. In particular, the protection layer 116 protects the organic light emitting element 130 and the inorganic light emitting element 140 from moisture and oxygen or various foreign materials. The protection layer 116 can also be disposed so as to cover the organic light emitting element 130, the inorganic light emitting element 140, the first bank 115a, and the second bank 115b. Further, the protection layer 116 can serve as an encapsulation layer enclosing the organic light emitting element 130 which is vulnerable to the moisture and oxygen.

In addition, the protection layer 116 can be formed of an insulating material. For example, the protection layer 116 can include inorganic insulating materials and organic insulating layers alternately laminated. That is, the protection layer 116 can be formed with inorganic insulating materials, such as silicon nitride (SiNx), silicon oxide (SiOx), and aluminum oxide (AlOx) and organic insulating materials, such as epoxy-based or acrylic-based polymer alternately laminated, but it is not limited thereto.

As shown, the light conversion members 150 is disposed on the protection layer 116. In particular, the light conversion members 150 converts light emitted from the inorganic light emitting element 140 and the organic light emitting element 130 into various color light. Each of the light conversion members 150 can be disposed so as to overlap each of the sub pixels SP. The light conversion member 150 can also be disposed so as to overlap both the inorganic light emitting element 140 and the organic light emitting element 130. Further, the light conversion members 150 can include a red light conversion member, a green light conversion member, and a blue light conversion member. As shown in FIG. 4, each of the light conversion members 150 includes a scattering layer 151 and a color filter 152.

In more detail, the scattering layer 151 is disposed on the protection layer 116. The scattering layer 151 mixes blue light emitted from the inorganic light emitting element 140 and green light and red light emitted from the organic light emitting element 130 to implement white light. The red light, the green light, and the blue light from the organic light emitting element 130 and the inorganic light emitting element 140 are also scattered from the scattering layer 151 and can be mixed as white light. Further, the red light, the green light, and the blue light are uniformly dispersed in the scattering layer 151 to improve luminance uniformity.

In addition, the scattering layer 151 can include a plurality of micro particles. Thus, the red light, the green light, and the blue light are scattered and dispersed in various directions by the micro particles of the scattering layer and are mixed as white light. For example, the scattering layer 151 can be a layer in which micro particles, such as titanium oxide (TiO2), zirconium oxide (ZrO2), aluminum oxide (Al2O3), zinc oxide (ZnO), barium titanate (BaTiO3), or hollow silica are dispersed in a base material, such as acryl, epoxy, siloxane, polyamide, or polyimide.

Further, referring to FIGS. 5A and 5B, light emitted from the inorganic light emitting element 140 and the organic light emitting element 130 can be uniformly emitted to the entire surface of the display device 100 by the scattering layer 151. In more detail, as shown in FIG. 5A, when there is no scattering layer 151, light emitted from the organic light emitting element 130 is not uniformly emitted onto the entire surface of the display device 100 so that the luminance uniformity according to a viewing angle can be lower. For example, when there is no scattering layer 151, most light emitted from the organic light emitting element 130 is emitted to a front area of the display device 100, that is, an area of 0°. Further, when there is no scattering layer 151, a smaller quantity of light is emitted to an area in a side direction of the display device 100, for example, to an area between approximately 15° and 60°. In contrast, the display device 100 according to the exemplary embodiment of the present disclosure including a scattering layer 151, light emitted from the organic light emitting element 130 is uniformly emitted to a front direction and a side direction of the display device 100.

Therefore, when there is no scattering layer 151, the quantities of light emitted from the organic light emitting element 130 to the front direction and the side direction of the display device 100 are different so that the luminance uniformity according to the viewing angle is low. Further, when there is a scattering layer 151, the quantities of light emitted from the organic light emitting element 130 to the front direction and the side direction of the display device 100 are implemented to be similar so that the luminance uniformity according to the viewing angle is improved more.

Referring to FIG. 5B, light emitted from the inorganic light emitting element 140 can also be uniformly emitted to the outside of the display device 100 by the scattering layer 151. For example, as shown, when there is no scattering layer 151, a quantity of light emitted to an area between 15° and 60° which is an area of the side direction of the display device 100 is more than a quantity of light emitted from the inorganic light emitting element 140 to a 0°-area which is an area of the front direction of the display device 100. When there is a scattering layer 151, light emitted from the inorganic light emitting element 140 is uniformly emitted from the area of the front direction of the display device 100 to the area of the side direction.

Accordingly, when there is no scattering layer 151, the quantities of light emitted from the inorganic light emitting element 140 to the front direction and the side direction of the display device 100 are different so that the luminance uniformity according to the viewing angle is low. Further, when there is a scattering layer 151, the quantities of light emitted from the inorganic light emitting element 140 to the front direction and the side direction of the display device 100 are implemented to be similar so that the luminance uniformity according to the viewing angle is improved more.

Accordingly, in the display device 100 according to the exemplary embodiment of the present disclosure, the scattering layer 151 is disposed on the organic light emitting element 130 and the inorganic light emitting element 140 to mix light emitted from the organic light emitting element 130 and the inorganic light emitting element 140 as white light. Therefore, the luminance uniformity of the display device can be improved.

Next, as shown in FIG. 4, the color filter 152 is disposed on the scattering layer 151 and converts white light mixed in the scattering layer 151 into any one of red light, green light, and blue light. For example, the color filter 152 can include a red color filter 152 for displaying red light, a green color filter 152 for displaying green light, and a blue color filter 152 for displaying blue light.

In addition, the color filter 152 transmits only light with a specific wavelength to be displayed and can absorb light with a remaining wavelength. For example, in order to display red light, the red color filter 152 transmits light in a red wavelength band, among the whiter light, and can absorb light in the remaining wavelength band.

Next, the black matrix 117 is disposed in an area between the light conversion member 150. As shown in FIG. 4, the black matrix 117 can be disposed on the protection layer 116 so as to enclose the light conversion members 150. The black matrix 117 can also divide an area in which each of the light conversion members 150 are disposed. Also, the black matrix 117 can shield light converted by the light conversion member 150 of each of the sub pixels SP so as not to be mixed. Further, the black matrix 117 absorbs light incident to the display device 100 from the outside to minimize a degradation of visibility due to external light which is reflected by the configuration in the display device 100. For example, the black matrix 117 includes a black component and is formed of an opaque resin including a dye, but is not limited thereto.

As shown, the second substrate 120 is disposed on the light conversion members 150 and the black matrix 117. In more detail, the second substrate 120 supports and protects various components included in the display device 100 and can be formed of an insulating material. For example, the second substrate 120 can be formed of glass or resin. Further, the second substrate 120 can be formed of polymer or plastics or can be formed of a material having flexibility.

In addition, when the white light is implemented by only the organic light emitting element 130, the red organic emission layer 132R and the green organic emission layer 132G and the blue organic emission are used together to implement white light. However, the blue organic emission layer has a shorter lifespan than the red organic emission layer 132R or the green organic emission layer 132G and has an inferior efficiency. Therefore, in order to stably implement the white light, a plurality of blue organic emission layers is preferable so that a process efficiency can be reduced.

Therefore, in the display device 100 according to the exemplary embodiment of the present disclosure, the inorganic light emitting element 140 having an excellent emission efficiency of blue light is used together with the organic light emitting element 130 to stably implement white light. The inorganic light emitting element 140 is a blue LED which emits blue light and has excellent luminous efficiency and lifespan more than the blue organic emission layer. Therefore, in each of the sub pixels SP, the organic light emitting element 130 including the green organic emission layer 132G and the red organic emission layer 132R and the inorganic light emitting element 140 which emits blue light are disposed together to implement white light with high purity and high luminance. Accordingly, in the display device 100 according to the exemplary embodiment of the present disclosure, the blue inorganic light emitting element 140 having a stable and high efficiency and an organic light emitting element 130 which emits green and red light are disposed in one sub pixel together to generate white light with a high purity.

Further, in the display device 100 according to the exemplary embodiment of the present disclosure, light emitted from the inorganic light emitting element 140 and the organic light emitting element 130 is uniformly emitted using the scattering layer 151 to improve the luminance uniformity of the display device 100. When there is no scattering layer 151, light emitted from the organic light emitting element 130 and the inorganic light emitting element 140 is not uniformly extracted from the front direction of the display device 100 to the side direction so that the luminance uniformity according to the viewing angle is low. Therefore, the scattering layer 151 which includes a plurality of micro particles scatters and disperses light emitted from the organic light emitting element 130 and the inorganic light emitting element 140 to extract light with uniform luminance from the front direction to the side direction of the display device 100. Accordingly, in the display device 100 according to the exemplary embodiment of the present disclosure, the scattering layer 151 is disposed in a light extraction direction of the organic light emitting element 130 and the inorganic light emitting element 140 to uniformly disperse the light to improve the luminance uniformity according to the viewing angle.

Also, the inorganic light emitting element 140 is connected to the anode 131 and the cathode 133 of the organic light emitting element 130 to drive the inorganic light emitting element 140. The inorganic light emitting element 140 can be disposed between the anode 131 and the cathode 133 of the organic light emitting element 130. In this instance, the first electrode 144 of the inorganic light emitting element 140 is disposed on the anode 131 to be electrically connected to the anode 131 and the driving transistor DT. Also, the second electrode 145 of the inorganic light emitting element 140 is disposed below the cathode 133 to be electrically connected to the cathode 133 and the power line. Accordingly, the anode 131 of the organic light emitting element 130 and the first electrode 144 of the inorganic light emitting element 140 are electrically connected to the driving transistor DT together. Further, the cathode 133 of the organic light emitting element 130 and the second electrode 145 of the inorganic light emitting element 140 are electrically connected to the power line together to be supplied with a driving current. Accordingly, the inorganic light emitting element 140 is disposed between the anode 131 and the cathode 133 of the organic light emitting element 130 to connect the inorganic light emitting element 140 and the driving transistor DT and the power line. Therefore, there is no need to form an electrode or a wiring line which separately connects the inorganic light emitting element 140, and the driving transistor DT and the power line and a structure of the display device 100 is simplified.

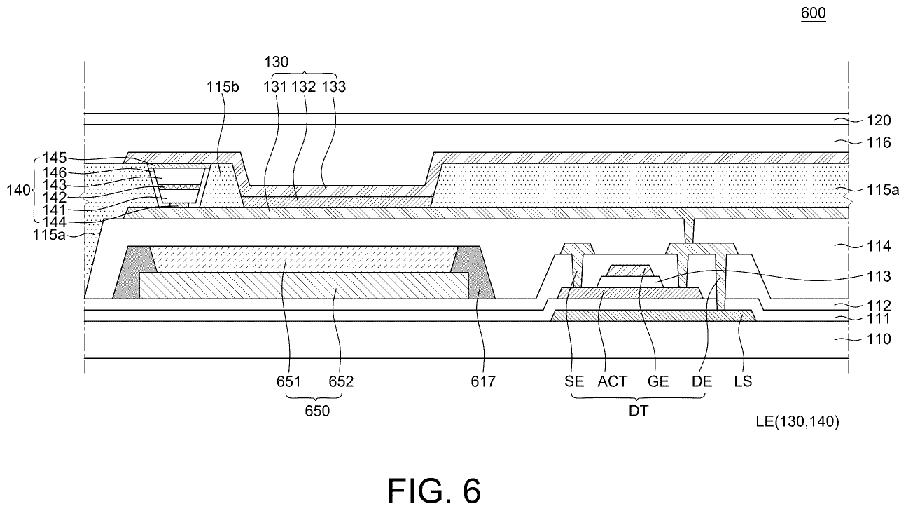

Next, FIG. 6 is a cross-sectional view of a sub pixel of a display device 600 according to another exemplary embodiment of the present disclosure. The display device 600 of FIG. 6 is a bottom emission type which is different from the display device 100 of FIGS. 1 to 4, but the other configuration is substantially the same, so that a redundant description will be omitted.

Referring to FIG. 6, the display device 600 is configured as a bottom emission type. For the bottom emission type, light emitted from the light emitting element LE can travel toward the bottom of the light emitting element LE. According to the bottom emission type, in order to reflect light emitted from the organic emission layer 132 to the top of the organic light emitting element 130, the anode 131 is formed of a transparent conductive material, such as indium tin oxide (ITO) or indium zinc oxide (IZO). Also, the cathode 133 can be formed of a conductive material having a low light transmittance. Accordingly, light emitted from the organic emission layer 132 transmits the anode 131 to travel toward the first substrate 110. Further, light emitted from the inorganic light emitting element 140 travels toward the anode 131 by the cathode 133 having a low light transmittance.

As shown, a light conversion member 650 is disposed below the organic light emitting element 130 and the inorganic light emitting element 140. In particular, the light conversion member 650 can be disposed between the interlayer insulating layer 112 and the planarization layer 114 so as to overlap the organic light emitting element 130 and the inorganic light emitting element 140. Also, a scattering layer 651 is disposed between the interlayer insulating layer 112 and the planarization layer 114 and a color filter 652 can be disposed between the scattering layer 651 and the interlayer insulating layer 112. Accordingly, light emitted from the organic light emitting element 130 and the inorganic light emitting element 140 can travel to the color filter 652 via the scattering layer 651.

Further, as shown, a black matrix 617 encloses the light conversion member 650. In more detail, the black matrix 617 can be disposed between the interlayer insulating layer 112 and the planarization layer 114 so as to enclose the light conversion member 650. For example, the color filter 652 is disposed on the interlayer insulating layer 112, the black matrix 617 is formed on the interlayer insulating layer 112 and the color filter 652, and the scattering layer 651 can be formed on the black matrix 617 and the color filter 652.

Also, FIG. 6 illustrates the light conversion member 650 and the black matrix 617 are disposed on the interlayer insulating layer 112, but the present disclosure is not limited thereto. For example, the light conversion member 650 and the black matrix 617 are formed to be in contact with the first substrate 110. The black matrix 617 can also be disposed so as to cover an upper portion of the first substrate 110 which is not covered by the light conversion member 650 while enclosing the light conversion members 650, like the black matrix 117 of FIG. 4. Accordingly, the black matrix 617 divides the area of the light conversion members 650 to suppress the color mixture of the light converted in the light conversion member 650 of each of the sub pixels SP.

Further, the black matrix 617 which covers a remaining area of the first substrate 110 excluding an area where the light conversion members 650 are disposed absorbs light which is incident to the display device 100 from the outside. Therefore, the degradation of the visibility due to the external light which is reflected from the configuration in the display device 100 can be minimized. Also, the light shielding layer LS and the buffer layer 111 are formed on the light conversion member 650 and the black matrix 617 which are in contact with the first substrate 110. As shown in FIG. 6, the driving transistor DT, the interlayer insulating layer 112, the gate insulating layer 113, and the planarization layer 114 are sequentially formed thereon to connect the light emitting elements (LE) 130 and 140 and the driving transistor DT.

Accordingly, in the display device 600 according to another exemplary embodiment of the present disclosure, the light conversion member 650 is disposed in an area below the organic light emitting element 130 and the inorganic light emitting element 140 to display images in a bottom emission manner. For example, the anode 131 of the organic light emitting element 130 is formed of a transparent conductive material and the cathode 133 is formed of a conductive material having a low light transmittance to reflect light emitted from the organic emission layer 132 and the inorganic light emitting element 140 toward the anode 131. Further, light emitted from the organic light emitting element 130 and the inorganic light emitting element 140 is incident to the light conversion member 650 disposed between the interlayer insulating layer 112 and the planarization layer 114 to be converted into various color light. Finally, the light which is converted by the light conversion member 650 travels toward the first substrate 110 to display images on the first substrate 110.

Thus, according to an aspect of the present disclosure, a display device includes a first substrate including a plurality of sub pixels, an organic light emitting element which is disposed in each of the sub pixels and includes an anode, an organic emission layer on the anode, and a cathode on the organic emission layer, and an inorganic light emitting element which is disposed in each of the sub pixels and is disposed between the anode and the cathode, a first electrode of the inorganic light emitting element is electrically connected to the anode and a second electrode of the inorganic light emitting element is electrically connected to the cathode.

In addition, the organic emission layer and the inorganic light emitting element can be disposed to be spaced apart from each other. The display device can further include a first bank which is disposed between the sub pixels and includes a plurality of openings in which the organic emission layer and the inorganic light emitting element are disposed, and a second bank which is disposed between the organic emission layer and the inorganic light emitting element in each of the sub pixels.

Also, the anode can extend over the second bank to be in contact with the first electrode and the cathode can extend over the second bank and is in contact with the second electrode. The inorganic light emitting element can also be disposed to be adjacent to an edge of each of the openings. Further, two side surfaces of four side surfaces of the inorganic light emitting element can be in contact with the first bank.

In addition, the organic emission layer can includes a red organic emission layer which emits red light and a green organic emission layer which emits green light and the inorganic light emitting element can further includes an active layer which is disposed between the first electrode and the second electrode and emits blue light. The display device can further include a light conversion member which is disposed so as to overlap the inorganic light emitting element and the organic light emitting element in each of the sub pixels, the light conversion member can include a color filter, and a scattering layer which is disposed between the color filter and the inorganic light emitting element and between the color filter and the organic light emitting element and includes a plurality of micro particles.

Also, the scattering layer can be configured to mix red light and green light emitted from the organic light emitting element and blue light emitted from the inorganic light emitting element to produce white light. The color filter can be configured to convert the white light into another color light.

In addition, the light conversion member can be disposed on the inorganic light emitting element and the organic light emitting element. The light conversion member can be disposed below the inorganic light emitting element and the organic light emitting element. The display device can further include a black matrix which is disposed between the sub pixels and is disposed so as to enclose the light conversion member.

The display device can further include a protection layer which covers the inorganic light emitting element and the organic light emitting element, the protection layer can be configured to protect the inorganic light emitting element and the organic light emitting element from moisture and oxygen. The inorganic light emitting element can be a micro light emitting diode (LED) and the organic light emitting element can be an organic light emitting diode (OLED).

Although the exemplary embodiments of the present disclosure have been described in detail with reference to the accompanying drawings, the present disclosure is not limited thereto and can be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. All the technical concepts in the equivalent scope of the present disclosure should be construed as falling within the scope of the present disclosure.

What is claimed is:

1. A display device, comprising:
a first substrate including a plurality of sub pixels;
an organic light emitting element disposed in each of the sub pixels and including an anode, an organic emission layer on the anode, and a cathode on the organic emission layer; and
an inorganic light emitting element disposed in each of the sub pixels between the anode and the cathode of the organic light emitting element,
wherein a first electrode of the inorganic light emitting element is electrically connected to the anode of the organic light emitting element and a second electrode of the inorganic light emitting element is electrically connected to the cathode of the organic light emitting element.

2. The display device according to claim 1, wherein the organic emission layer and the inorganic light emitting element are spaced apart from each other.

3. The display device according to claim 2, further comprising:
a first bank disposed between the plurality of sub pixels and including a plurality of openings in which the organic emission layer and the inorganic light emitting element are disposed; and
a second bankdisposed between the organic emission layer and the inorganic light emitting element in each of the plurality of sub pixels.

4. The display device according to claim 3, wherein the anode extends over the second bank and contacts the first electrode and the cathode extends over the second bank and contacts the second electrode.

5. The display device according to claim 3, wherein the inorganic light emitting element is disposed adjacent to an edge of each of the plurality of openings.

6. The display device according to claim 3, wherein two side surfaces of four side surfaces of the inorganic light emitting element contact the first bank.

7. The display device according to claim 1, wherein the organic emission layer of the organic light emitting element includes a red organic emission layer emitting red light and a green organic emission layer emitting green light, and
wherein the inorganic light emitting element further includes an active layer disposed between the first electrode and the second electrode and emitting blue light.

8. The display device according to claim 7, further comprising:
a light conversion member overlapping the inorganic light emitting element and the organic light emitting element in each of the plurality of sub pixels,
wherein the light conversion member includes:
a color filter; and
a scattering layer disposed between the color filter and the inorganic light emitting element and between the color filter and the organic light emitting element and including a plurality of micro particles.

9. The display device according to claim 8, wherein the scattering layer is configured to mix red light and green light emitted from the organic light emitting element and blue light emitted from the inorganic light emitting element to produce white light.

10. The display device according to claim 9, wherein the color filter is configured to convert the white light into another color light.

11. The display device according to claim 8, wherein the light conversion member is disposed on the inorganic light emitting element and the organic light emitting element.

12. The display device according to claim 8, wherein the light conversion member is disposed below the inorganic light emitting element and the organic light emitting element.

13. The display device according to claim 8, further comprising:
a black matrix disposed between the plurality of sub pixels and enclosing the light conversion member.

14. The display device according to claim 1, further comprising:
a protection layer covering the inorganic light emitting element and the organic light emitting element and protecting the inorganic light emitting element and the organic light emitting element from moisture and oxygen.

15. The display device according to claim 1, wherein the inorganic light emitting element is a micro light emitting diode (LED) and the organic light emitting element is an organic light emitting diode (OLED).

16. A display device, comprising:
a plurality of sub pixels disposed in row and columns on a substrate and spaced apart from each other with a first bank therebetween;
an organic light emitting element disposed in each of the sub pixels and including an anode, an organic emission layer on the anode, and a cathode on the organic emission layer;
an inorganic light emitting element disposed in a corner edge region of each of the sub pixels; and
a light conversion member overlapping the organic light emitting element and the inorganic light emitting element in each sub pixel and configured to configure to convert white light implemented by a combination of blue light emitted from the inorganic light emitting element and red and green light emitted from the organic light emitting element into a predetermined color light,
wherein the organic light emitting element and the inorganic light emitting element are spaced apart from each other with a second bank therebetween, and
wherein the anode and the cathode of the organic light emitting element overlap the inorganic light emitting element and are electrically connected to first and second electrodes of the inorganic light emitting element.

17. The display device according to claim 16, wherein in a first row of the plurality of sub pixels, the inorganic light emitting element is disposed in upper left corner regions and upper right corner regions.

18. The display device according to claim 17, wherein in a second row of the plurality of sub pixels below the first row, the inorganic light emitting element is disposed in lower left corner regions and lower right corner regions.

19. The display device according to claim 16, wherein in a first two columns of the plurality of sub pixels, the inorganic light emitting element is disposed in upper left corner regions and lower right corner regions, and
wherein in a second two columns of the plurality of sub pixels, the inorganic light emitting element is disposed in upper right corner regions and lower right corner regions.

20. The display device according to claim 16, wherein the anode and the cathode of the organic light emitting element extend beyond an outer edge of the first electrode of the inorganic light emitting element.

21. The display device according to claim 16, wherein the inorganic light emitting element is disposed in an area between the first bank and the second bank.
